(19) United States
(12) Patent Application Publication
(10) Pub. No.: US 2024/0217120 A1
(43) Pub. Date: Jul. 4, 2024

(54) MAGNETIC HANDLING DEVICE

(71) Applicant: CENTRE NATIONAL DE LA RECHERCHE SCIENTIFIQUE, Paris (FR)

(72) Inventor: Richard HAETTEL, Notre Dame de Mesage (FR)

(21) Appl. No.: 18/558,749

(22) PCT Filed: May 13, 2022
(86) PCT No.: PCT/EP2022/063034

§ 371 Date: Nov. 3, 2023

(30) Foreign Application Priority Data
May 19, 2021 (FR) FR2105231

(51) Int. Cl. B25J 15/06; B25J 1/00

(52) U.S. Cl. CPC B25J 15/0608; B25J 1/00

(57) ABSTRACT

A magnetic handling device for handling an object in a workspace, the device including a tubular case of a non-magnetic or weakly magnetic material, including adjacent sliding faces, a first end of the tubular case open and in communication with the workspace, a ferromagnetic armature slidably arranged in the tubular case according to the longitudinal axis of the tubular case, a handling shaft extending through the tubular case, the handling shaft coupled to the ferromagnetic armature to slide toward or in the workspace, an actuator outside the tubular case, including magnets forming a magnetic system with the ferromagnetic armature, the actuator configured to make the ferromagnetic armature slide according to the tubular case longitudinal axis, actuator inner surfaces and outer surfaces of the ferromagnetic armature configured to match with the sliding faces, the ferromagnetic armature configured to be pressed on the sliding faces of the tubular case by the magnets.

### TECHNICAL FIELD

The present invention relates to a magnetic handling device for handling an object in a workspace, such as a vacuum chamber or an annealing furnace.

Without limitation, the field of the invention is that of mechanical positioning systems.

### PRIOR ART

Magnetic handling devices, which may also be called magnetic sticks, allow transmitting, via a magnetic coupling, a translational movement or a combined translational/rotational movement through a wall of a workspace, for example a vacuum or controlled atmosphere chamber. This type of chamber is necessary, for example, in the manufacturing process of semiconductor components.

A magnetic stick comprises a stick body, typically cylindrical, provided with a movable axis inside the body and a bearing allowing guiding the axis as it comes out of the stick body. In general, the axis is equipped with roller bearings or plain bearings enabling it to slide inside the body of the stick. The axis can be moved using a handle sliding on the stick body, thanks to a magnetic coupling between the axis and the handle generating a return force. Objects in the workspace can be handled with the shaft of the stick, whose end may comprise a clamp or a paddle for grasping or moving the object.

In particular, the use of a magnetic stick allows getting rid of seals, ensuring perfect sealing of vacuum or controlled atmosphere enclosures.

However, the design of the stick, in particular with a bearing and other guiding elements, might cause constraints linked to the bulk, to the mechanical coupling of the axis with the object to be moved or to the temperature of use of the stick.

An object of the invention is to provide a magnetic handling device that can overcome these drawbacks.

### DISCLOSURE OF THE INVENTION

The present invention aims to provide a magnetic handling device allowing handling significant payloads.

The present invention also aims to provide a robust magnetic handling device which can be implemented with workspaces at very high temperatures and/or pollutants.

The present invention also aims to provide a magnetic handling device that is not bulky.

At least one of these aims is achieved with a magnetic handling device, adapted to handle an object in a workspace, the device comprising:
a tubular case made of a non-magnetic or weakly magnetic material, comprising at least two adjacent so-called sliding faces, a first end of the tubular case being open and in communication with the workspace,
a ferromagnetic armature slidably arranged in the tubular case according to the longitudinal axis of the tubular case, a handling shaft extending through the tubular case, the handling shaft being coupled to the ferromagnetic armature so as to be able to slide towards or in the workspace,
an actuator arranged outside the tubular case, comprising a plurality of magnets forming a magnetic system with the ferromagnetic armature, the actuator being configured to make the ferromagnetic armature slide according to the longitudinal axis of the tubular case,
   inner surfaces of the actuator and outer surfaces of the ferromagnetic armature being configured to match with the at least two sliding faces, the ferromagnetic armature being configured to be pressed on the at least two sliding faces of the tubular case by the magnets.

Hereafter, the term “handling an object” should be understood to include supporting, grasping, moving, positioning, managing the position of, etc., the object.

The device according to the present invention implements a magnetic system generating both a radial magnetic force as well as a return force. An object can be moved or handled by moving the actuator along the tubular case. Thanks to this translational movement, the object can be moved in a workspace, like for example an annealing furnace, inserted therein or removed therefrom.

The return force is necessary to make the ferromagnetic armature slide synchronously with the actuator when the latter is moved. Thanks to the return force, an actuating or constraining force is transmitted via the handling shaft to the object that should be handled.

The radial magnetic force is necessary to press the magnetic armature against the sliding faces of the tubular case. A “V”-like shaped guide is formed by the sliding faces. Guidance of the ferromagnetic armature, and therefore of the handling shaft coupled thereto, while bearing on the sliding faces allows suppressing the mechanical operating clearance of the handling shaft. Thus, the handling shaft could withstand significant rotational torques without rotating around its axis. It is not necessary for the handling shaft to be equipped with guiding bearings or sliding bearings. This also allows increasing the payload at the tip of the handling shaft compared to sticks of the prior art.

Importantly, the device according to the present invention does not require a bearing at the open end of the tubular case. Indeed, the ferromagnetic armature remaining pressed against the sliding faces, the handling shaft therefore does not need to be supported at the outlet of the tubular case.

The absence of a bearing improves degassing of the device for use under ultra-high vacuum. Indeed, the movement of the molecules is facilitated thanks to the absence of small section passages.

The device according to the present invention is not subject to the constraints related to the presence of a bearing or guide bearings of the handling shaft. Hence, the device could be used with workspaces in which the handling shaft is heated to high temperatures or subjected to pollution, like in an oven or a deposition enclosure for example.

Thanks to the absence of constraints that a bearing might present at the outlet of the tubular case, the shape of the handling shaft implemented in the device may be very variable. The section of the shaft may be oval, round, square, etc., and the diameter of the shaft may vary over its length.

Advantageously, a support or handling tool, such as an axis or a paddle made of quartz, may be coupled to the handling shaft allowing carrying and/or handling an object. This tool may be coupled to the handling shaft using a mechanical coupling part.

A quartz axis is particularly suitable for use in chemical vapor deposition (CVD) reactors. Quartz withstands thermal shock very well and barely outgasses at high temperatures. It is very chemically resistant compared to the products used in CVD reactors. This resistance also enables it to be easily decontaminated chemically.

Of course, other materials may be used for the handling tool.

Moving the actuator may be performed manually. Handling the actuator by hand is particularly effortless and easy to implement.

Alternatively, the actuator may be moved using a motor. This enables more accurate and delicate movements.

According to one embodiment, the tubular case may have an essentially rectangular section with four faces including two adjacent sliding faces.

According to an advantageous example, the section of the tubular case may be square.

The manufacture of such a tubular case is particularly effortless.

According to one embodiment, the handling shaft may be coupled to the ferromagnetic armature by means of a coupling part.

Alternatively, the handling shaft may be directly fastened to the ferromagnetic armature.

According to one embodiment, the ferromagnetic armature may comprise at least two wheels on one face placed on one of the sliding faces of the tubular case and at least one wheel on another face placed on another sliding face, so as to be able to roll on the sliding faces.

The torque generated by the payload, cantilevered on the handling shaft, is distributed over the wheels of the ferromagnetic armature. The contact between the wheels and the sliding faces is linear (and not punctual). This linear contact allows handling heavy loads with the device according to the invention without premature wear of the sliding faces.

In particular, the wheels may comprise bearings.

According to one example, the bearings may comprise balls, preferably non-magnetic.

Advantageously, each face of the ferromagnetic armature placed on the sliding faces may comprise two wheels.

Alternatively, and depending on the use of the handling device, the ferromagnetic armature may comprise bearings, in particular made of polymer, arranged on the faces placed on the sliding faces.

According to one embodiment, the magnetic system may comprise a plurality of magnetic circuits.

The number of magnetic circuits determines the magnetic strength of the magnetic system. The addition of a magnetic circuit increases the radial magnetic force as well as the return force. The number may be adapted depending on the desired application of the device according to the invention.

According to one embodiment, the ferromagnetic armature may comprise a one-piece.

Such a one-piece can be easily machined and is very robust.

Alternatively, the ferromagnetic armature may comprise a plurality of ferromagnetic parts.

According to some embodiments, the ferromagnetic armature may be made of soft iron, of low-alloy steel or of iron-cobalt.

Of course, other suitable materials may be implemented.

According to one embodiment, the magnets are arranged according to a Halbach matrix.

An arrangement of magnets according to a Halbach matrix allows increasing the magnetic field on the side of the ferromagnetic armature while significantly reducing it on the other side (towards the outside of the actuator). Thus, such an arrangement of magnets allows improving the performances of the magnets, as well as reducing the bulk of the arrangement.

Alternatively, it is possible to use pieces of soft iron arranged on top of two adjacent magnets, inside the actuator, to form the magnetic circuit.

According to some examples, the magnets may be made of neodymium-iron-boron or of samarium-cobalt.

Other permanent magnet materials may also be implemented.

According to one embodiment, the actuator may comprise rollers arranged on at least two of its inner surfaces, so as to be able to roll on the tubular case.

Alternatively, the actuator may comprise bearings, for example polymer bearings, arranged on at least two of its inner surfaces, so as to be able to slide on the tubular case.

According to one embodiment, the actuator may consist of a sleeve arranged all around the tubular case and having an internal section adapted to the section of the tubular case.

The sleeve forms a handle for a good grip when manually moving the actuator.

Alternatively, the actuator may surround the tubular case only partially. For example, it may have the shape of a half-cylinder. This actuator type enables it to be removed from the tubular case radially and not axially.

The actuator may be removed for steaming the handling shaft, for example. Also, the movement of such an actuator on the tubular case, which may comprise flanges, vacuum gauges, etc., is facilitated.

This could also solve problems related to objects (flanges, vacuum gauges, etc.) located proximate to the sticks body and which would block the movement of the actuator.

Advantageously, the magnetic system may be off-centred according to the axis of the ferromagnetic armature with respect to its centre.

This off-centring allows better compensating for the torque created by the handling shaft.

When the magnetic system is off-centred towards the rear of the ferromagnetic armature (compared to a movement in the direction of the workspace), the acceptable load on the handling shaft may be increased when the device is in the horizontal position.

According to one embodiment, the coupling part may comprise a second ferromagnetic armature, the device further comprising a second actuator arranged outside the tubular case and comprising a plurality of magnets forming a magnetic system with the second ferromagnetic armature, the second actuator being configured to rotate radially around the tubular case, while driving the coupling part and the handling shaft in rotation.

The device according to this embodiment allows combining translations and rotations for more complex movements or positioning of the object in the workspace.

### DESCRIPTION OF THE FIGURES AND EMBODIMENTS

Other advantages and features will appear upon examining the detailed description of non-limiting examples, and from the appended drawings wherein:

FIGS. 1(a) (perspective view) and 1(b) (longitudinal sectional view) are schematic illustrations of a non-limiting embodiment of a handling device according to the invention;

FIG. 2 is a schematic cross-sectional view of a non-limiting embodiment of a handling device according to the invention;

FIG. 3 is a schematic longitudinal sectional view of an example of an actuator implemented in the handling device according to the invention;

FIG. 4 is a schematic illustration of an example of a ferromagnetic armature implemented in the handling device according to the invention; and

FIG. 5 is a schematic illustration of an example of a magnetic system implemented in the handling device according to the invention.

It should be understood that the embodiments that will be described hereafter are in no way limiting. In particular, one could imagine variants of the invention comprising only a selection of features described hereafter isolated from the other described features, if this selection of features is sufficient to confer a technical advantage or to differentiate the invention from the prior art. This selection comprises at least one preferably functional feature without structural details, or with only part of the structural details if this part alone is sufficient to confer a technical advantage or to differentiate the invention from the prior art.

In particular, all of the described variants and embodiments could be combined together if nothing opposes this combination on a technical level.

In the figures, elements common to several figures could keep the same reference.

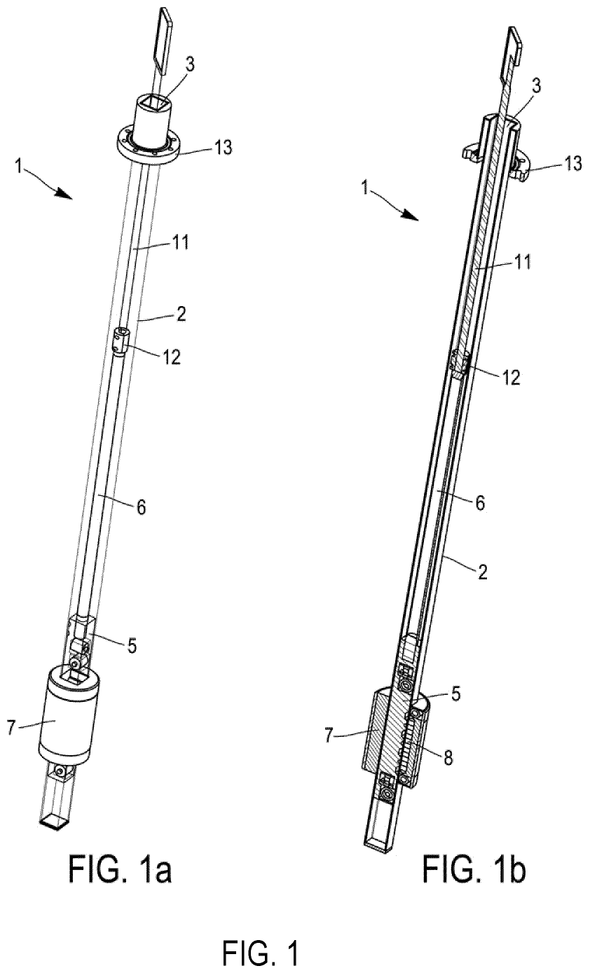

FIG. 1 shows schematic illustrations of a magnetic handling device according to an embodiment of the invention (perspective view in FIG. 1(a) and longitudinal section view in FIG. 1(b), respectively).

The handling device 1 comprises a tubular case 2, or tube 2. The tubular case 2 is made of a non-magnetic or weakly magnetic material. One end 3 of the case 2 is open in order to be able to communicate with a workspace in which an object should be handled, transferred or positioned. This open end is equipped with an adaptation flange 13 enabling the mechanical coupling of the device 1 with the workspace, for example a vacuum enclosure. The tubular case 2 may be manufactured by extrusion or formed from sheet metal and then welded. In the latter case, the internal weld is removed (“scraped”) so that the internal section is smooth.

The device 1 also comprises a ferromagnetic armature 5 inside the tube 2 as well as a handling shaft 6 extending through the tube 2. The handling shaft 6 is rigidly coupled to the ferromagnetic armature 5. The handling shaft 6 may be fastened directly to the ferromagnetic armature 5, as illustrated in FIG. 1. Fastening may also be achieved by means of a coupling part.

Preferably, the handling shaft 6 and the tubular case 2 are made of stainless steel.

As illustrated in FIG. 1, a paddle 11 is fastened to the handling shaft 6 by means of a mechanical coupling part 12. The paddle 11 allows carrying an object to be handled on its blade.

The handling device 1 comprises an actuator 7. The actuator 7 is arranged outside the tube 2. In the embodiment as illustrated in FIG. 1, the actuator 7 is in the form of a sleeve 7 slidably arranged all around the tube 2.

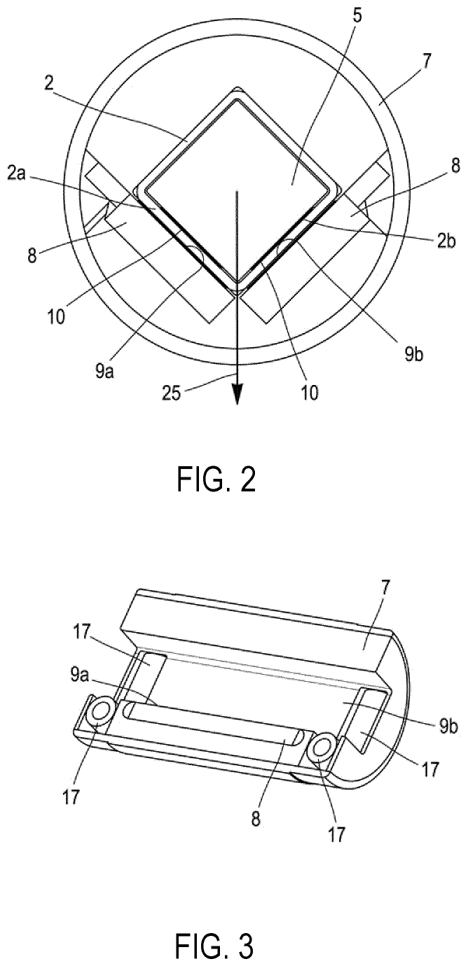

FIG. 2 shows a cross-section of the handling device 1 according to the embodiment of FIG. 1. The actuator 7 comprises a plurality of magnets 8. In the example of FIG. 2, two magnets 8 are arranged along two inner faces 9a, 9b of the actuator 7. For example, the magnets 8 may be made of neodymium-iron-boron or of samarium-cobalt.

FIG. 3 shows a longitudinal section of the actuator 7. In the illustrated example, the actuator 7 comprises two rollers 17 on the inner faces 9a, 9b provided with magnets 8. The rollers 17 may be mounted on needle bearings. For example, the rollers 17 may be made of polyetheretherketone (PEEK).

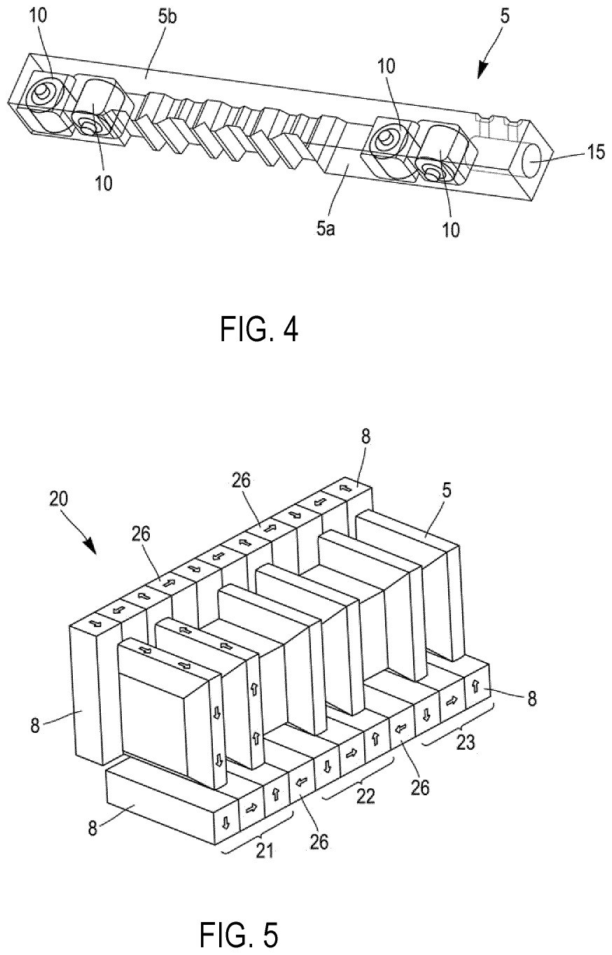

An embodiment of the ferromagnetic armature 5 is shown in FIG. 4. The ferromagnetic armature 5 is a machined one-piece comprising two faces 5a, 5b provided with two wheels 10 or bearings, respectively. The ferromagnetic armature 5 also comprises a bore 15 for inserting the handling shaft 6 therein and fastening it with bolts.

The ferromagnetic armature 5 may be made of soft iron, of low-alloy steel, of iron-cobalt or of another suitable material. After machining, the ferromagnetic armature 5 may be subjected to a heat treatment in order to optimise its magnetic properties.

Of course, other ferromagnetic materials may be used for the armature. In the illustrated embodiment, the ferromagnetic armature 5 forms a carriage capable of rolling inside the tubular case 2.

The wheels 10 may comprise hybrid bearings provided with rings made of steel, balls made of ceramic and cages made of PEEK. These hybrid bearings can be used without grease.

The tubular case 2 comprises at least two adjacent so-called sliding faces. In the embodiment shown in FIG. 2, the two sliding faces 2a, 2b form a right angle therebetween pointing downwards. The ferromagnetic armature 5 is pressed on the two sliding faces 2a, 2b of the tubular case 2 by the magnets 8 of the actuator 7, so that the wheels 10 of the ferromagnetic armature 5 are in contact with the sliding faces 2a, 2b.

The sliding faces 2a, 2b may form an angle other than a right angle, as long as the opening of the angle allows pressing a ferromagnetic armature 5 with a suitable shape on the two sliding faces.

The actuator 7 can be grasped in order to make the ferromagnetic armature 5 and the handling shaft 6 slide according to the longitudinal axis of the tubular case 2. The ferromagnetic armature 5 can then be moved along the tubular case 2 while remaining pressed against the sliding faces 2a, 2b of the case 2.

As illustrated in FIG. 1, the actuator 7 is in the form of a handle 7. The handle can be moved manually.

The magnets 8 of the actuator and the ferromagnetic armature 5 form a magnetic system. The magnetic system 20 of the device of FIG. 1 is illustrated in FIG. 5. The ferromagnetic armature 5 is illustrated only partially (without the ends equipped with wheels). The magnetic system 20 comprises three blocks 21, 22, 23, each comprising twice three magnets 8 and a portion of the ferromagnetic armature 5. Each of the blocks 21, 22, 23 forms a magnetic circuit. The magnetic fluxes are indicated by arrows. The blocks 21, 22, 23 are separated from each other by two magnets 26 (a magnet 26 on each of the two inner faces of the actuator). Of course, the number of blocks may be different, depending on needs in terms of magnetic force.

In the magnetic system 20 of FIG. 5, the magnets 8 are arranged according to a Halbach matrix. This arrangement is obtained by rotating the magnetic orientations by 90° between successive magnets 8.

A strong magnetic coupling between the actuator 7 and the ferromagnetic armature 5 allows holding these two components pressed on either side of the sliding faces 2a, 2b of the tube 2. The attractive force exerted radially between the actuator 7 and the ferromagnetic armature 5 allows counterbalancing the torque induced by the handling shaft 6 fastened to the ferromagnetic armature 5 and the paddle 11. The resultant 25 of the radial force exerted between the actuator 7 and the ferromagnetic armature 5 is illustrated in FIG. 2.

In the example shown in FIG. 4, the magnetic system 20 is off-centred according to the axis of the ferromagnetic armature 5, with respect to its centre, towards the side opposite to the handling shaft 6. Indeed, this off-centring allows better counterbalancing the torque induced by the handling shaft and the payload.

The internal section of the actuator 7 is adapted to the section of the tube 2. Indeed, at least the two inner surfaces 9a, 9b provided with magnets 8 of the actuator 7 should match with the sliding faces 2a, 2b of the tube 2. In the embodiment shown in FIG. 1, the external section of the tube 2 as well as the internal section of the actuator 7 are square.

In the same way, the external section of the ferromagnetic armature 5 is adapted to the section of the tubular case 2. The ferromagnetic armature 5 should be pressed against the sliding faces 2a, 2b with at least the two faces equipped with wheels 10 by the radial magnetic force. In practice, the armature 5 could completely fill the internal section of the tube 2 while leaving an operating clearance.

Thus, the magnets 8 are arranged the closest to the ferromagnetic armature 5, allowing obtaining a magnetic system 20 with an optimum performance. The distance between the magnets 8 and the armature 5 is such that it allows interposing the tube 2, while leaving a space necessary for the operating clearance as well as the wheels 10 of the armature 5 and the bearings 17 of the actuator 7.

The tubular case 2 may have a square section (as illustrated in FIGS. 1 and 2), rectangular or triangular, or in the form of a segment of a circle (i.e. a triangle with a hemispherical side).

According to another embodiment (not shown), the handling device according to the invention comprises a second ferromagnetic armature, arranged in a coupling part between the first ferromagnetic armature, as described hereinabove, and the handling shaft. This second ferromagnetic armature interacts with a second actuator arranged outside the tubular case. The second actuator comprises a plurality of magnets thereby forming a magnetic system with the second ferromagnetic armature. The second actuator is configured to be able to rotate radially around the tubular case. Thanks to the magnetic coupling between the magnets of the second actuator and the second ferromagnetic armature, the coupling part as well as the handling shaft are driven in rotation when the second actuator is rotated around the tube.

Thanks to this alternative design, the translation movement of the handling shaft of the device described hereinabove may be coupled to a rotational movement of the handling shaft. Thus, more complex handling operations of the object are possible.

Of course, the invention is not limited to the examples that have just been described and many arrangements could be made to these examples without departing from the scope of the invention.

1. A magnetic handling device adapted to handle an object in a workspace, the magnetic handling device comprising:
a tubular case made of a non-magnetic or weakly magnetic material, comprising at least two adjacent so-called sliding faces, a first end of the tubular case being open and in communication with the workspace,
a ferromagnetic armature slidably arranged in the tubular case according to a longitudinal axis of the tubular case,
a handling shaft extending through the tubular case, the handling shaft being coupled to the ferromagnetic armature so as to be able to slide towards or in the workspace,
an actuator arranged outside the tubular case, comprising a plurality of magnets forming a magnetic system with the ferromagnetic armature, the actuator being configured to make the ferromagnetic armature slide according to the longitudinal axis of the tubular case,
inner surfaces of the actuator and outer surfaces of the ferromagnetic armature being configured to match with the at least two sliding faces, the ferromagnetic armature being configured to be pressed on the at least two sliding faces of the tubular case by the magnets.

2. The magnetic handling device according to claim 1, wherein a section of the tubular case is square.

3. The magnetic handling device according to claim 1, wherein a tool for handling the object is coupled to the handling shaft.

4. The magnetic handling device according to claim 1, wherein the ferromagnetic armature comprises at least two wheels on one face placed on one of the at least two sliding faces of the tubular case and at least one wheel on another face placed on another of the at least two sliding faces, so as to be able to roll on the at least two sliding faces.

5. The magnetic handling device according to claim 1, wherein the magnetic system comprises a plurality of magnetic circuits.

6. The magnetic handling device according to claim 1, wherein the ferromagnetic armature comprises a one-piece.

7. The magnetic handling device according to claim 1, wherein the ferromagnetic armature comprises a plurality of ferromagnetic parts.

8. The magnetic handling device according to claim 1, wherein the ferromagnetic armature is made of soft iron, low-alloy steel or iron-cobalt.

9. The magnetic handling device according to claim 1, wherein the magnets are arranged according to a Halbach matrix.

10. The magnetic handling device according to claim 1, wherein the magnets are made of neodymium-iron-boron or of samarium-cobalt.

11. The magnetic handling device according to claim 1, wherein the actuator comprises rollers arranged on at least two of its inner surfaces, so as to be able to roll on the tubular case.

12. The magnetic handling device according to claim 1, wherein the actuator comprises bearings arranged on at least two of its inner surfaces, so as to be able to slide on the tubular case.

13. The magnetic handling device according to claim 1, wherein the actuator is in the form of a sleeve arranged all around the tubular case and having an internal section adapted to the section of the tubular case.

14. The magnetic handling device according to claim 1, wherein the magnetic system is off-centred according to an axis of the ferromagnetic armature with respect to its centre.

15. The magnetic handling device according to claim 1, wherein the magnetic handling device further comprises a motor configured to move the actuator.

16. The magnetic handling device according to claim 1, wherein the handling shaft is coupled to the ferromagnetic armature by means of a coupling part comprising a second ferromagnetic armature, the magnetic handling device further comprising a second actuator arranged outside the tubular case and comprising a plurality of magnets forming a magnetic system with the second ferromagnetic armature, the second actuator being configured to rotate radially around the tubular case, while driving the coupling part and the handling shaft in rotation.
